(19) United States
(12) Patent Application Publication
(10) Pub. No.: US 2025/0140648 A1
(43) Pub. Date: May 1, 2025

(54) BONDING A WAFER WITH A SUBSTRATE TO A WAFER WITH BACKSIDE INTERCONNECT WIRING

(71) Applicant: International Business Machines Corporation, Armonk, NY (US)

(72) Inventors: HUIMEI ZHOU, Albany, NY (US); Ruilong Xie, Niskayuna, NY (US); Terence B. Hook, Jericho Center, VT (US); Kisik Choi, Watervliet, NY (US)

(21) Appl. No.: 18/495,832

(22) Filed: Oct. 27, 2023

(51) Int. Cl. H01L 23/48; H01L 23/367; H01L 25/065; H01L 27/146; H10B 12/00

(52) U.S. Cl. CPC H01L 23/481; H01L 23/3677; H01L 25/0657; H10B 12/038; H10B 12/053; H10B 12/056; H10B 12/36; H10B 12/39; H10F 39/026; H10F 39/811; H01L 2225/06541

(57) ABSTRACT

Aspects of the disclosed invention provide a semiconductor structure for a semiconductor chip with two layers of semiconductor devices, where the first layer of semiconductor devices directly contacts a semiconductor substrate and connects to a first frontside interconnect wiring. The first layer of semiconductor devices includes at least one trench semiconductor device such as a deep trench capacitor. The first frontside interconnect wiring is electrically connected to the second frontside interconnect wiring by one or more joined metal plugs. The second layer of active devices connects to a backside power delivery network and the second frontside interconnect wiring. The semiconductor chip with two layers of semiconductor devices that are bonded together provides one layer of semiconductor devices capable of being in a portion of the semiconductor substrate and a second layer of semiconductor devices with a backside power delivery network.

### BACKGROUND

The disclosure relates generally to semiconductor device manufacturing. The disclosure relates particularly to using a hybrid bonding process to join two wafers by an oxide layer and metal plugs where one wafer includes a semiconductor substrate and the second wafer includes backside interconnect wiring.

The amount of data we process is rapidly increasing at a rate higher than that of Moore's law. Increasing system performance requirements, driven at least in part by the increasing use of artificial intelligence, continue to drive tighter pitches in semiconductor devices and smaller semiconductor chips. For logic scaling at the two-nanometer node, planar and non-planar semiconductor device structures, such as metal-oxide-semiconductor field-effect transistors (MOSFETs), must be scaled to smaller dimensions.

With evolution of reduced-size transistors, semiconductor technology has progressed from planar transistor designs to three-dimensional type finFET designs which are further evolving into gate-all-around transistor designs. With increasing demands to reduce the dimensions of transistor devices, nanosheet field-effect transistors (FETs) help achieve a reduced device footprint while maintaining device performance. A nanosheet FET device contains one or more portions of layers of semiconductor channel material having a vertical thickness that is substantially less than its width. A typical nanosheet FET includes a plurality of stacked nanosheets extending between a pair of source/drain epitaxial regions. The nanosheet FET device may be a gate-all-around device in which a gate surrounds the channels of the nanosheet FET devices. Utilizing stacked nanosheets, Gate-All-Around nanosheet field-effect transistors (GAA nanosheet FETs) and 3D-stacked complementary metal-oxide semiconductor (CMOS) devices such as complementary field-effect transistor devices will be important to continuing to extend beyond Moore's Law.

GAA nanosheet (or nanowire) FET devices are a viable option for continued device scaling. GAA nanosheet FET devices have been recognized as excellent candidates to achieve improved power performance and area scaling compared to FinFET technology. GAA nanosheet FET devices can provide high drive currents due to wide effective channel width (Weff) while maintaining short-channel control. However, in many cases, backside power delivery networks need to be coupled with GAA nanosheet FETs for performance and back-end-of-line (BEOL) wiring congestion issues.

Furthermore, as the semiconductor industry continues to drive beyond the ten-nanometer (nm) technology node and into the two-nanometer technology node with tighter pitches and increasing performance, increased use of backside interconnect layers for a backside power delivery network is emerging. Creating backside interconnect layers below the front-end-of-line semiconductor devices provides improved power performance and more routing options for semiconductor devices relieving some of the BEOL wiring congestion. Utilizing a backside power delivery network can enable ten to thirty-five percent logic area scaling reduction in a two-nanometer technology node that utilizes GAA nanosheet field-effect transistors. A backside power delivery network improves semiconductor device gate delay and reduces BEOL wiring congestion. However, shrinking the dimensions of wiring dimensions in the interconnect wiring of the frontside and backside of the semiconductor chips in pursuit of Moore's Law also means the wires have a reduced cross-sectional area, which drives up the resistance-capacitance product (RC) of the interconnect system. This results in increasing signal delay. With the 7 nm technology node in the development phase and the 5 nm node moving into development, transistor scaling gets ever more complex, and the performance benefits gained at the front-end-of-line (i.e., the transistors) can easily be undone if the back-end-of-line technology doesn't provide similar performance improvements. The RC delay issues due to the BEOL interconnect wiring are becoming more important. For example, a delay of more than 30% is expected when moving from the 10 nm to the 7 nm node.

### SUMMARY

The following presents a summary to provide a basic understanding of one or more embodiments of the disclosure. This summary is not intended to identify key or critical elements or delineate any scope of the particular embodiments or any scope of the claims. Its sole purpose is to present concepts in a simplified form as a prelude to the more detailed description that is presented later.

Aspects of the disclosed invention relate to a semiconductor structure for a semiconductor chip that includes at least two layers of semiconductor devices, where the first layer of semiconductor devices contacts a semiconductor substrate and connects to a first frontside interconnect wiring and where the second layer of semiconductor devices connects to a second frontside interconnect wiring and a backside power delivery network.

According to an aspect of the invention, there is provided a semiconductor structure for the semiconductor chip with a semiconductor substrate with a first plurality of semiconductor devices that includes a first frontside interconnect wiring connected by one or more first contacts to the first plurality of semiconductor devices. A second bond layer electrically connects with a first bond layer. The second frontside interconnect wiring connects the second bond layer and one or more first contacts to a second plurality of semiconductor devices. The plurality of backside contacts connects the second plurality of semiconductor devices to a backside power delivery network.

Aspects of the disclosed invention include a method of forming a semiconductor structure. The method includes forming a first plurality of semiconductor devices on a first wafer substrate with a first frontside interconnect wiring, where the first plurality of semiconductor devices includes at least one trench semiconductor device. The method includes depositing a first bond layer with one or more first metal plugs. Furthermore, the method includes forming a second plurality of semiconductor devices on a second wafer substrate with a second frontside interconnect wiring. The method includes depositing a second bond layer with one or more second metal plugs. The method includes flipping the second wafer substrate on top of the first wafer substrate. The method includes bonding the first wafer substrate to the second wafer substrate. The method includes removing the second wafer substrate and forming backside interconnect wiring for a backside power delivery network. The method includes dicing the first wafer substrate to form one or more semiconductor chips.

### BRIEF DESCRIPTION OF THE DRAWINGS

The above and other aspects, features, and advantages of various embodiments of the present invention will be more apparent from the following description taken in conjunction with the accompanying drawings.

FIG. 1 depicts a cross-sectional view of a semiconductor structure of a first wafer with semiconductor devices and a metal plug in a top oxide layer, in accordance with an embodiment of the present invention.

FIG. 2 depicts a cross-sectional view of a semiconductor structure of a second wafer with semiconductor devices and a metal plug in a top oxide, in accordance with an embodiment of the present invention.

FIG. 3 depicts a cross-sectional view of the semiconductor structure after bonding the first wafer and the second wafer, in accordance with an embodiment of the present invention.

FIG. 4 depicts a cross-sectional view of the semiconductor structure after removing a semiconductor substrate of the second wafer, depositing a backside interlayer dielectric (ILD), forming backside contacts, and backside interconnect wiring, in accordance with an embodiment of the present invention.

FIG. 5 is one example of the operational steps of a method to form a final assembly of the semiconductor structure depicted in FIG. 4, in accordance with an embodiment of the present invention.

FIG. 6 depicts a cross-sectional view of another example of the two bonded wafers with the backside interconnect wiring on the second wafer, in accordance with an embodiment of the present invention.

FIG. 7 depicts a cross-sectional view of the semiconductor structure of FIG. 4 after depositing a thermal interface material (TMI) and adding a cooling plate, in accordance with an embodiment of the present invention.

### DETAILED DESCRIPTION

Embodiments of the present invention recognize that the shrinking wiring dimensions in the interconnect wiring of the frontside and backside interconnect wiring of semiconductor chips means the wires have a reduced cross-sectional area, which drives up the resistance-capacitance product (RC) of the interconnect system in the BEOL interconnect wiring. This results in increasing signal delay. As the semiconductor device scaling gets more complex, the performance benefits gained at the front-end-of-line semiconductor devices (e.g., the transistors) can easily be undone if the back-end-of-line technology doesn't provide similar performance improvements. The RC delay issues due to the BEOL interconnect wiring are becoming more challenging to improve semiconductor chip performance.

Embodiments of the present invention recognize the need to provide backside interconnect wiring to reduce wiring congestion in the frontside interconnect wiring. The backside interconnect wiring can be formed on the backside of a thinned semiconductor substrate or without a thinned semiconductor substrate. However, with a thinned semiconductor substrate only a limited amount of RC reduction can occur since there would be more parallel capacitance with existing silicon.

Embodiments of the present invention recognize that providing semiconductor devices formed on and in the semiconductor substrate can provide device architectures meeting specific high-performance or high-power requirements and allows the formation of semiconductor devices such as deep trench decoupling capacitors in the semiconductor substrate to aide in achieving the high-performance semiconductor chip.

Aspects of the present invention provide a method of forming a semiconductor structure composed of at least two layers of active semiconductor devices where each layer of the active devices is formed on a semiconductor substrate. Frontside interconnect wiring forms over each of the two layers of active semiconductor devices on the two semiconductor substrates using back-end-of-line (BEOL) processes. A deposition of a bond layer such as an oxide layer with embedded metal plugs on each of the two frontside interconnect wiring occurs. Using hybrid bonding, the two bond layers and the metal plugs are joined. The semiconductor substrate is removed from one exposed surface of the bond semiconductor structure. A number of backside contacts are formed connecting to backside interconnect wiring created using known BEOL processes. The backside interconnect wiring can be a backside power delivery network. Dicing of the semiconductor structure, in some embodiments, results in a number of semiconductor chips.

The method of forming the semiconductor structure results in a semiconductor structure, which can be a semiconductor chip, that includes a semiconductor substrate with a first plurality of semiconductor devices, where at least one of the semiconductor devices is a trench device formed in a portion of the semiconductor substrate. Frontside interconnect wiring connects, by contacts and/or vias, one or more of the plurality of semiconductor devices to at least one metal plug where the metal plug is bonded and electrically connected to at least one second metal plug formed above a second plurality of semiconductor devices on a second semiconductor substrate. The second metal plug connects to a second frontside interconnect wiring where the second frontside interconnect wiring connects by one or more contacts and/or vias to a second plurality of semiconductor devices. The second plurality of semiconductor devices connect to a backside interconnect wiring forming a backside power delivery network (BSPDN). To form the backside interconnect wiring, the second semiconductor substrate is removed. In this way, the semiconductor chip has one side with a semiconductor substrate and the other side with a BSPDN.

Detailed embodiments of the claimed structures and methods are disclosed herein. The method steps described below do not form a complete process flow for manufacturing integrated circuits, such as semiconductor devices. The present embodiments can be practiced in conjunction with the integrated circuit fabrication techniques currently used in the art and only so much of the commonly practiced process steps are included as are necessary for an understanding of the described embodiments. The figures represent cross-section portions of a semiconductor structure after fabrication and are not drawn to scale, but instead are drawn to illustrate the features of the described embodiments. Specific structural and functional details disclosed herein are not to be interpreted as limiting, but merely as a representative basis for teaching one skilled in the art to variously employ the methods and structures of the present disclosure. In the description, details of well-known features and techniques may be omitted to avoid unnecessarily obscuring the presented embodiments.

References in the specification to “one embodiment”, “other embodiment”, “another embodiment”, “an embodiment”, etc., indicate that the embodiment described may include a particular feature, structure or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. The terms “overlying”, “atop”, “over”, “on”, “positioned on” or “positioned atop” mean that a first element is present on a second element wherein intervening elements, such as an interface structure, may be present between the first element and the second element. The term “direct contact” means that a first element and a second element are connected without any intermediary conducting, insulating or semiconductor layers at the interface of the two elements.

In the interest of not obscuring the presentation of the embodiments of the present invention, in the following detailed description, some of the processing steps, materials, or operations that are known in the art may have been combined together for presentation and for illustration purposes and in some instances may not have been described in detail. Additionally, for brevity and maintaining a focus on distinctive features of elements of the present invention, description of previously discussed materials, processes, and structures may not be repeated with regard to subsequent Figures. In other instances, some processing steps or operations that are known may not be described. It should be understood that the following description is rather focused on the distinctive features or elements of the various embodiments of the present invention.

Reference is now made to the Figures. The Figures provide schematic cross-sectional illustrations of semiconductor devices at intermediate stages of fabrication, according to one or more embodiments of the invention. For purposes of the present invention, the terms wafer, wafer substrate, and semiconductor substrate can be considered interchangeable. The device provides schematic representations of the devices of the invention and are not to be considered accurate or limiting with regard to device element scale.

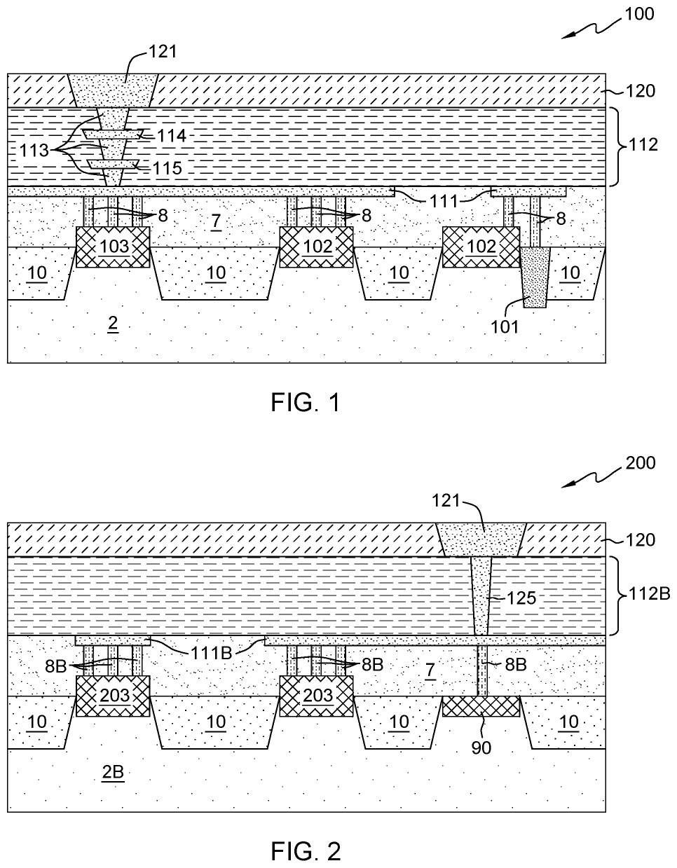

FIG. 1 depicts a cross-sectional view of a semiconductor structure of first wafer 100 with deep trench device 101, fin field-effect transistors (finFET) devices 102, and logic device 103 and metal plug 121 in bond layer 120, in accordance with an embodiment of the present invention. As depicted, FIG. 1 includes semiconductor substrate 2 with deep trench device 101 shallow trench isolation (STI) 10, finFET devices 102, logic device 103, device contacts 8, dielectric 7, metal layer 111, frontside interconnect wiring 112 including at least vias 113, landing pad 114, landing pad 115 in the various layers of interconnect wiring (not shown) in frontside interconnect wiring 112, bonding layer 120 on the top surface of frontside interconnect wiring 112 with metal plug 121 embedded in bonding layer 120. In various embodiments, finFET devices 102, logic device 103, and deep trench device 101 are a layer of semiconductor devices (e.g., active devices and passive devices) residing on or in a portion of semiconductor substrate 2. In various embodiments, finFET devices 102, logic device 103, and deep trench device 101 form in one or more portions of the first metal layer (e.g., M0 metal layer) above semiconductor substrate 2.

Semiconductor substrate 2 can be composed of any known semiconductor material such as but not limited to silicon, silicon germanium (SiGe), Ge, or any other semiconductor material used in forming semiconductor devices. In various embodiments, semiconductor substrate 2 is a bulk wafer composed of a single layer of a semiconductor material.

Deep trench device 101 may be any type of deep trench or trench device formed in a portion of semiconductor substrate 2. For example, deep trench device 101 can be a passive device or a memory device. In various embodiments, deep trench device 101 is a deep trench capacitor (DTCAP) which also be known as a deep trench capacitor (DTC) or a deep trench de-coupling capacitor (DTDCAP). Deep trench device 101 can also be an embedded dynamic random-access memory (EDRAM), a complementary metal-oxide semiconductor (CMOS) image sensor, an electrostatic device surrounding one or more STI 10, or other type of trench device formed in substrate 2. While one deep trench device 101 is depicted in FIG. 1, more than one deep trench device 101 can be present in first wafer 100.

Two finFET devices 102 are depicted in first wafer 100 of FIG. 1, however, in other examples, one or more finFET devices 102 may be present. In one example, no finFET devices 102 are present in first wafer 100. As previously discussed, finFET devices 102 could have a thick oxide in the device which can provide specific required high-power I/O support.

Logic devices 103 can be any type of semiconductor logic device. For example, logic device 103 can be a nanosheet device such as a nanosheet gate-all-around (GAA) FET. In other examples, logic device 103 can be a nanowire style FET, complementary FET (CFET), or a vertical FET (VFET) but logic device 103 is not limited to these examples. While not specifically depicted in FIG. 1, as known to one skilled in the art, first wafer 100 may include other semiconductor devices such as various memory devices or other passive devices (resistors, inductors, etc.) which can be formed directly on or in semiconductor substrate 2 of first wafer 100.

Device contacts 8 connecting finFET devices 102 and logic device 103 to metal layer 111 may be any type of device contact (e.g., gate contact, source/drain contact). Device contacts 8 can be in dielectric 7. In various embodiments, metal layer 111 can be an M1 metal layer, which can be a middle-of-line (MOL) metal layer above the semiconductor devices in first wafer 100. As known to one skilled in the art, any number of metal layers such as metal layer 111 may be present in the MOL and in the interconnect wiring formed using known back end of line (BEOL) semiconductor processes interconnect wiring where the interconnect wiring formed by BEOL semiconductor processes is depicted in FIG. 1 as frontside interconnect wiring 112.

Metal layer 111 can be composed of any metal or metal alloy used in semiconductor chip interconnect wiring (e.g., copper (Cu), tungsten (W), ruthenium (Ru), cobalt (Co), nickel (Ni), and alloys of these metals). In various embodiments, metal layer 111 is a middle-of-line metal layer. In some embodiments, metal layer 111 is the M1 metal layer which may be considered a middle-of-line layer or in some cases, may be considered a first metal layer of the frontside interconnect wiring 112 (not depicted in FIG. 1). Frontside interconnect wiring 112 can be formed using known back end of line (BEOL) semiconductor processes on the frontside of first wafer 100. Frontside interconnect wiring 112, as known to one skilled in the art, can be composed of patterned multiple metal layers (not specifically depicted), vias, and layers of dielectric material (not specifically labelled) such as various layers of interlayer dielectric (ILD) deposited over the various semiconductor device contacts (e.g., contacts 8) in a dielectric material and metal layer 111. As depicted in FIG. 1, frontside interconnect wiring 112 includes stacked vias 113 on landing pad 114 and landing metal 115 that connect metal layer 111 to metal plug 121 although many additional vias, dielectric layers, and metal layers (not depicted in FIG. 1) may be present in frontside interconnect wiring 112. In some cases, stacked vias 113 may be a single via or a super via. A super via may connect two non-adjacent metal layers without contacting a metal layer between the two non-adjacent layers. In other examples, more than one of stacked vias 113 or metal plugs 121 may be present in first wafer 100.

Bond layer 120 resides on the top surface of first wafer 100 directly on the surface of frontside interconnect wiring 112. In various embodiments, bond layer 120 is an oxide layer. Bond layer 120 can be any type of bond layer or oxide material layer used in hybrid bonding. As known to one skilled in the art, hybrid copper bonding creates a permanent bond, also known as a direct bond, that combines a dielectric bond (SiOx where x is a number greater than 0) with embedded metal (e.g., copper) to form interconnections. In other embodiments, bond layer 120 is one of another bond layer used in wafer-to-wafer bonding such as a polymer layer or a thin adhesive layer. Bond layer 120 includes one or more metal plugs 121. Using known lithography, metal deposition processes (e.g., chemical vapor deposition (CVD), atomic layer deposition ALD), and a planarization, for example, metal plugs 121 can formed in bond layer 120.

In various embodiments, metal plug 121 is a copper metal plug. Metal plug 121 can be composed of metal or metal alloy used in hybrid bonding or wafer-to-wafer bonding. For example, metal plug 121 can be composed of but not limited to, one of indium (In), tungsten (W), copper (Cu), or titanium (Ti). Each metal plug 121 contacts an exposed metal pad on the top surface of frontside interconnect wiring 112 and has an exposed top surface.

FIG. 2 depicts a cross-sectional view of a semiconductor structure of second wafer 200 with logic devices 203, passive device 90, and metal plug 121 in bond layer 120 on a top surface of second wafer 200, in accordance with an embodiment of the present invention.

As depicted, FIG. 2 includes logic devices 203 and passive device 90, however, second wafer 200 is not limited to these devices and may include any number of other memory devices, logic devices, and passive devices where the various semiconductor devices (logic, memory, and passives) are designed without extending into semiconductor substrate 2B. In other words, the semiconductor devices including active and passive devices (i.e., logic devices 203 and passive device 90) formed on second wafer 200 do not extend into semiconductor substrate 2 below STI 10. In various embodiments, logic devices 203 and passive device 90 are a layer of semiconductor devices above semiconductor substrate 2B. As known to one skilled in the art, the layer of semiconductor devices above semiconductor substrate 2B of second wafer 200 is not limited to logic devices 203 and passive device 90 but may include other semiconductor devices.

In various embodiments, each of logic devices 203 is a gate-all-around FET device (GAA FET) formed using stacked nanosheet semiconductor layers. In other embodiments, logic devices 203 are one or more of a nanosheet gate-all-around FET device, a finFET device, or a vertical FET (VFET) device, but are not limited to these semiconductor devices. Logic devices 203 can be any type of semiconductor logic devices that are formed above and/or on the semiconductor substrate 2B. As depicted in FIG. 2, logic devices 203 do not extend below STI 10 (i.e., there are no deep trench semiconductor devices in or on semiconductor substrate 2B).

Passive device 90 may be any type of passive device. For example, passive device 90 can be, but is not limited to, one or more of a resistor, thermistor, or shunt FET type protection diode which does not require a portion of the semiconductor devices to extend below STI 10 (e.g., devices that reside above the bottom surface of STI 10 and are not trench devices).

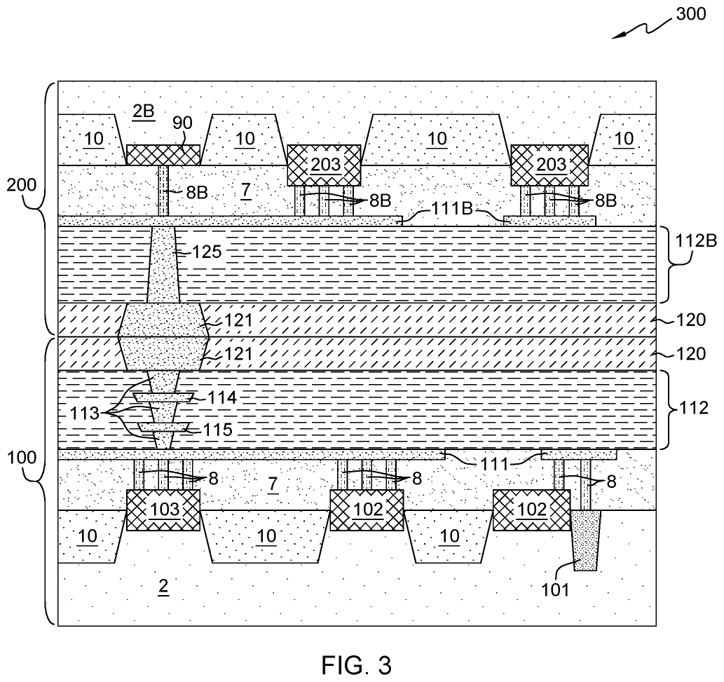

As depicted, FIG. 2 includes second wafer 200 with semiconductor substrate 2B, STI 10, logic devices 203, passive device 90, contacts 8B in dielectric 7, metal layer 111B, super via 125, frontside interconnect wiring 112B, metal plug 121, and bond layer 120. STI 10, contacts 8B, metal layer 111B, bond layer 120, metal plug 121, and frontside interconnect wiring 112B are essentially the same or similar to STI 10, contacts 8, metal layer 111, bond layer 120, metal plug 121, and frontside interconnect wiring 112 (e.g., formed with similar or the same materials and known processes) except that frontside interconnect wiring 112B include super via 125. Super via 125 can connect two non-adjacent metal layers without contacting a metal layer between the two non-adjacent metal layers. As known to one skilled in the art, super via 125 may alternatively be formed by stacking a number of vias and via landing pads (not depicted in FIG. 2) to connect various layers of frontside interconnect wiring 112B and/or metal layer 111B and metal plug 121. As discussed with respect to FIG. 1, more than one metal plug 121 may be present in second wafer 200. Metal plug 121 in first wafer 100 and metal plug 121 in second wafer 200 can be formed in bond layer 120 to align with each other when second wafer 200 is flipped and placed over first wafer 100 as depicted later in FIG. 3.

In various embodiments, semiconductor substrate 2B is composed of a multi-layer wafer. For example, semiconductor substrate 2B could be a silicon germanium (SiGe)-on-Silicon (SGS) wafer or semiconductor-on-insulator wafer and can be composed of any known combination of semiconductor material or insulator material used for SOI wafers. In some embodiments, semiconductor substrate 2B is a bulk semiconductor wafer composed of a single layer. In these examples, semiconductor substrate 2B may be composed of any semiconductor material (e.g., Si, SiGe, Ge, etc.).

FIG. 3 depicts a cross-sectional view of the semiconductor structure with first wafer 100 bonded to second wafer 200, in accordance with an embodiment of the present invention. As depicted, FIG. 3 includes the elements of FIG. 1 and FIG. 2 when second wafer 200 is flipped and bonded to first wafer 100. Bond layer 120 contacting frontside interconnect wiring 112 can be composed of a dielectric material such as an oxide with one or more embedded metal plug 121 contacting via 113 can be joined to bond layer 120 contacting frontside interconnect wiring 112B can be composed of a dielectric material such as an oxide with one or more embedded metal plug 121 contacting a metal via or super via 125. Each of bond layer 120 and metal plug 121 contacting each of frontside interconnect wiring 112 and 112B are bonded together in FIG. 3.

Second wafer 200 can be flipped and each of metal plug 121 exposed on the surface of second wafer 200 aligned with a corresponding metal plug 121 on first wafer 100. During the bonding of first wafer 100 to second wafer 200, metal plugs 121 in bond layer 120 on first wafer 100 are aligned and joined to metal plugs 121 in bond layer 120 of second wafer 200. In various embodiments, using known hybrid bonding processes, second wafer 200 is joined to first wafer 100. Bond layer 120 and one or more of metal plug 121 on the exposed top surface of first wafer 100 bonds to bond layer 120 and one or more of metal plug 121 on the exposed surface of flipped second wafer 200 are joined, for example, using hybrid bonding or other known wafer-to-wafer and metal pad to metal pad bonding process.

After bonding first wafer 100 and second wafer 200, the joined or bonded metal plug 121 in each of first wafer 100 and second wafer 200 connect frontside interconnect wiring 112 on first wafer 100 and frontside interconnect wiring 112B on second wafer 200. As depicted in FIG. 3, semiconductor substrate 2B of second wafer 200 is the exposed top surface of the two joined wafers after bonding first wafer 100 and second wafer 200.

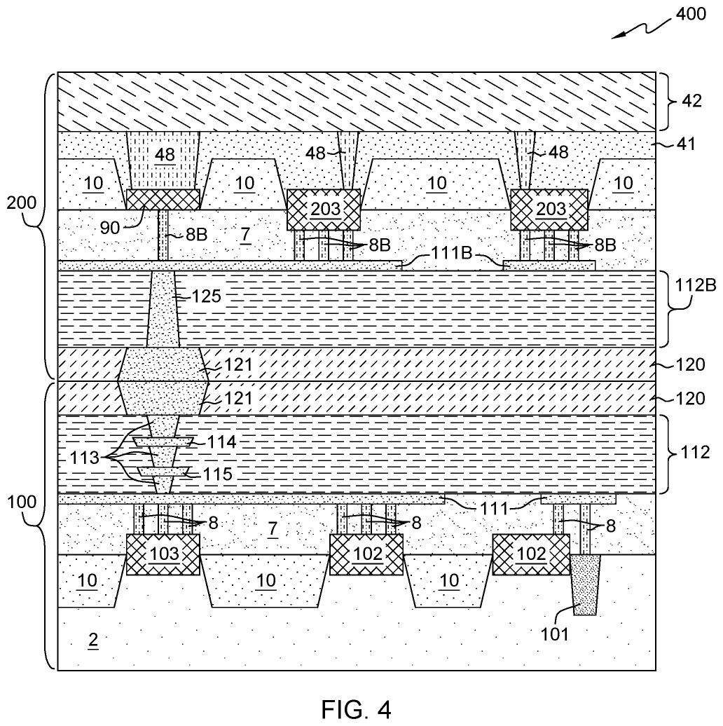

FIG. 4 depicts a cross-sectional view of semiconductor structure 400 of joined first wafer 100 and second wafer 200 after removing semiconductor substrate 2B of the second wafer 200, depositing backside interlayer dielectric (BILD) 41, forming backside contacts 48, and backside interconnect wiring 42, in accordance with an embodiment of the present invention. As depicted, FIG. 4 includes the elements of FIG. 3 without semiconductor substrate 2B and with the addition of BILD 41, backside contacts 48, and backside interconnect wiring 42. In some cases, backside interconnect wiring 42 may also be a backside power delivery network or BSPDN.

The removal of semiconductor substrate 2B, deposition and planarization of BILD 41, and formation of backside interconnect wiring 42 can occur using known semiconductor processes. Semiconductor structure 400 includes first wafer 100 with semiconductor substrate 2 and the remaining portions and semiconductor devices of second wafer 200 after removing semiconductor substrate 2B to form backside interconnect wiring 42. After removing semiconductor substrate 2B, hereinafter, second wafer 200 without the wafer substrate of semiconductor substrate 2B will be called second semiconductor structure 200.

Using known semiconductor processes, backside interconnect wiring 42 can be formed on BILD 41 and backside contacts 48 of second semiconductor structure 200. In this way, semiconductor structure 400 provides both the semiconductor devices of first wafer 100 where first wafer 100 includes semiconductor substrate 2 with embedded device 101, finFET devices 102 with a thick gate oxide, and logic device 103, which may be a GAA FET while second semiconductor structure 200 with semiconductor substrate 2B removed provides backside interconnect wiring 42 along with logic devices 203 which can be GAA FET for advanced logic devices with feature sizes below 10 nm and in the 2-5 nm range. Backside interconnect wiring 42 provides additional wiring layers to reduce wiring congestion in frontside interconnect wiring 112B and can provide a BSPDN.

Semiconductor structure 400 provides two joined wafers (e.g., two hybrid bonded wafers) with any number of metal plugs 121 in each of first wafer 100 and second semiconductor structure 200 that connect frontside interconnect wiring 112 and frontside interconnect wiring 112B. As depicted, semiconductor structure 400 includes first wafer 100 with semiconductor substrate 2 that can provide embedded devices or trench devices in substrate 2 such as an EDRAM or a DTDCAP, and second semiconductor structure 200 can provide backside interconnect wiring or a BSPDN.

As depicted in semiconductor structure 400, first wafer 100 also includes finFET devices 102 along with embedded device(s) 101 and logic device 103 where finFET devices 102 can provide a thick gate oxide for improved semiconductor chip performance and second semiconductor structure 200 includes logic devices 203 such as GAA FETS that can increase the drive current for a given footprint area aiding in device footprint reduction for the increasing device performance demands of the industry as feature sizes extend below 5 nm.

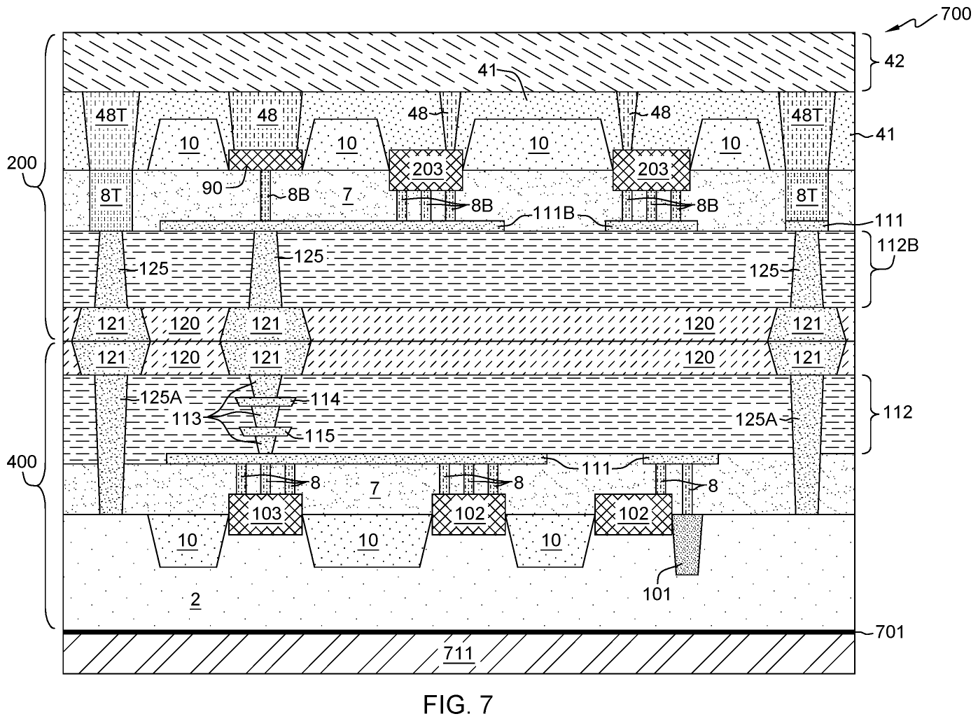

In this way, embodiments of the present invention provide two joined or bonded wafers with electrical connections between them provided by one or more metal plugs 121 where one wafer provides a semiconductor substrate for embedded devices (EDRAM, DTDCAP, etc.) and the second wafer without a semiconductor substrate provides backside interconnect wiring for additional wiring. The two joined wafers can provide semiconductor chip designers with the ability to form semiconductor structures that can use a combination or any combination of embedded devices or deep trench devices and thick gate oxide devices such as finFET devices, planar devices with a semiconductor substrate (e.g., planar FETs), memory devices such as DRAM devices, phase-change RAM, and EDRAM formed using a deep trench in the semiconductor substrate along with GAA FET for reduced feature sizes and improved overall density, and backside interconnect wiring (e.g., BSPDN) on a semiconductor structure with the semiconductor substrate removed. In other words, after forming the semiconductor devices on two wafers or semiconductor substrates with a bond layer and metal plugs and bonding the two wafers together, one of the two semiconductor substrates is removed to form the BSPDN. The other semiconductor substrate remains in the bonded semiconductor structure of FIGS. 4 and 7 where the remaining semiconductor substrate can provide embedded or trench devices such as DTDCAP or EDRAM devices.

In various embodiments, after forming the backside interconnect wiring on the second semiconductor structure 200 of the two bonded wafers (i.e., first wafer 100 and second semiconductor structure 200), the two bonded wafers joined by bond layer 120 and metal plugs 121 is diced forming more than one semiconductor chip with at least the elements depicted in FIG. 4. In an embodiment, the two bonded wafers form a semiconductor chip.

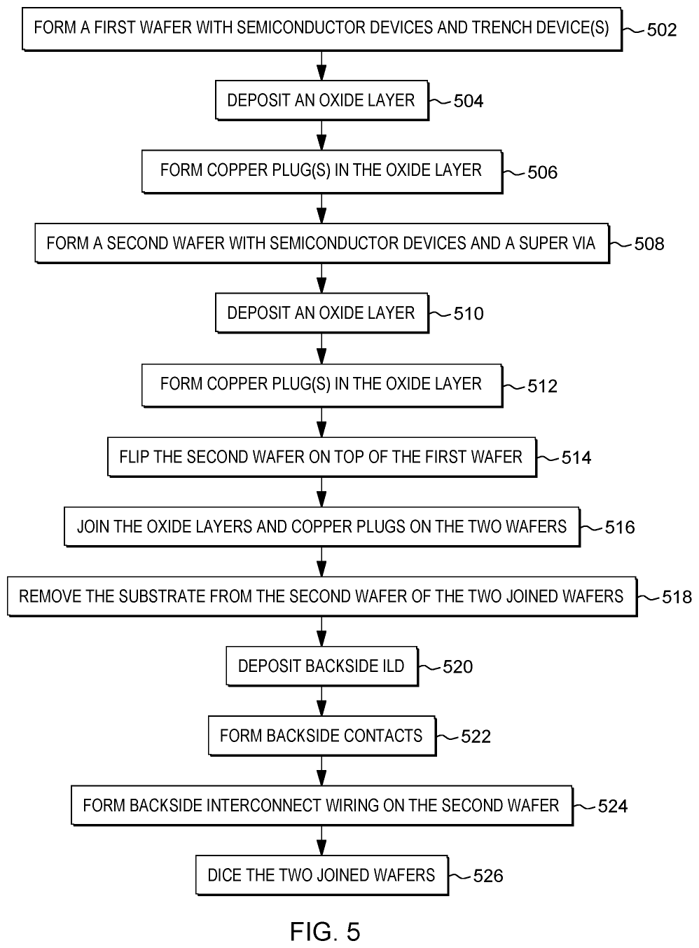

FIG. 5 is one example of the operational steps of a method to form semiconductor structure 400 depicted in FIG. 4, in accordance with an embodiment of the present invention.

In step 502, form a first wafer with semiconductor devices and trench devices in a semiconductor substrate. Using known semiconductor device formation processes, any number of semiconductor devices can be formed. For example, a number of trench devices such as deep trench capacitors, embedded DRAM devices, and any other trench device that can be formed in a semiconductor substrate may be formed in the semiconductor substrate of the first wafer. Additionally, a number I/O devices such as fin-type I/O devices, finFET devices providing a thick gate oxide, planar FET devices that may be formed with a semiconductor substrate, memory devices, and GAA FET devices may be formed in the first wafer but, the devices in the first wafer are not limited to these devices.

In step 504, a deposition of an oxide layer occurs. The oxide layer may be any oxide material deposited by CVD. ALD, or other suitable deposition process on the exposed top surface of the first wafer. The oxide layer may be composed of any oxide material suitable for hybrid bonding. In other examples, a layer of a different material, such as a polymer or an adhesive layer suitable for another wafer-to-wafer bonding process can be deposited instead of the oxide layer in step 504.

In step 506, form copper plug(s) in the oxide layer. Using known lithography, etching, metal deposition, and planarization processes, one or more metal plugs can be formed or embedded in the oxide layer. In other examples, the metal plugs can be composed of Cu, W, Ti, In, Au, or any other suitable metal material or metal alloys for hybrid bonding or capable of being bonded or joined in another wafer-to-wafer bonding process. In an alternative embodiment, a first semiconductor chip is diced from the first wafer.

In step 508, form a second wafer with semiconductor devices and a super via. In some embodiments, one or more stacked vias can replace one or more super vias. Using known semiconductor device formation processes, any number of semiconductor devices can be formed. For example, a number of semiconductor devices such as GAA FETs, passive devices, memory devices, finFET devices can be formed in the second wafer.

In step 510, deposit an oxide layer. As previously discussed in step 504, the oxide layer may be any oxide material deposited by CVD, ALD, or other suitable deposition process on the exposed top surface of the first wafer. The oxide layer may be composed of any oxide material suitable for hybrid bonding. In other examples, a layer of a different material, such as a polymer or an adhesive layer suitable for another wafer-to-wafer bonding process can be deposited instead of the oxide layer.

In step 512, form copper plug(s) in the oxide layer. Using known lithography, etching, metal deposition, and planarization processes, one or more metal plugs can be formed or embedded in the oxide layer. The metal plugs can be composed of Cu, W, Ti, In, Au, or any other suitable metal material or metal alloys for hybrid bonding or capable of being bonded or joined in another wafer-to-wafer bonding process. In an alternative embodiment, a second semiconductor chip is diced from the first wafer.

In step 514, flip the second wafer on top of the first wafer. Using known semiconductor alignment tools and systems, align each of the one or more copper plugs in the second wafer with the one or more copper plugs in the first semiconductor wafer. In an alternative embodiment, the second semiconductor chip is flipped.

In step 516, join the oxide layers and the copper plugs in the two wafers using a hybrid bonding process or any other suitable known wafer-to-wafer bonding process. In various embodiments, using a hybrid bonding process, the oxide layers and the copper plugs are joined. After bonding, the first wafer and the second wafer are joined together in a combined wafer semiconductor structure where semiconductor devices, interconnect wiring layers, and semiconductor substrates reside above and below the oxide bond layer. The first wafer and the second wafer are electrically connected by the bonded or joined copper plugs in the bonded oxide layers. In an alternative embodiment, the first semiconductor chip is bonded to the second semiconductor chip.

After joining the first wafer to the second wafer, the first wafer can include at least logic devices such as finFET devices or planar FET devices with a thick gate oxide in addition to other devices such as GAA FET, memory devices, passive devices, semiconductor devices requiring contact with the semiconductor substrate, and trench devices requiring at least a partial embedding into the semiconductor substrate or wafer (e.g., deep trench passive or active devices). The second wafer can include semiconductor devices that do not need to be embedded in the semiconductor substrate but instead reside above the bottom of STI 10. For example, the second wafer can include GAA FET devices, VFETs, passive devices, other logic devices, and memory devices that do not require a trench or deep trench in the semiconductor substrate of the second wafer. The second wafer, as formed, with body isolated devices or semiconductor devices that do not embed or need contact with the second wafer, frontside interconnect wiring, and the backside interconnect wiring bonds to the first wafer. For example, hybrid bonding of the oxide layers and metal plugs on the second wafer to the corresponding oxide layer and metal plugs of the first wafer. After aligning and bonding the metal plugs on the first wafer with the metal plugs on the second wafer, the resulting semiconductor structure provides the first wafer with semiconductor devices that may include deep trench semiconductor devices in at least a portion of the semiconductor structure (e.g., the first wafer). In an embodiment, the two bonded wafers form a semiconductor chip.

In step 518, remove the second wafer using known semiconductor wafer removal processes (e.g., wafer grind and/or wafer etching). After removing the second wafer, deposit a backside ILD over the exposed surfaces of the second wafer in step 520.

In step 522, form backside contacts on the second wafer. Using known contact formation processes, form contacts to the exposed surfaces of the various semiconductor devices in the second wafer. After performing a chemical-mechanical polish to planarize the backside contacts and remove excess contact metal, in step 524, form backside interconnect wiring on the second wafer. Using known BEOL processes, the backside interconnect wiring can be formed on the exposed surfaces of BILD and backside contacts of the second wafer. The second wafer is without a semiconductor substrate. In various embodiments, the backside interconnect wiring of the second wafer is a BSPDN.

In step 526, dice the semiconductor structure with the first wafer to form more than one semiconductor chip. Each of the semiconductor chips can include various active and passive devices including trench devices in or on the first wafer and a BDPSN is over the backside interlayer dielectric that replaces the removed second wafer.

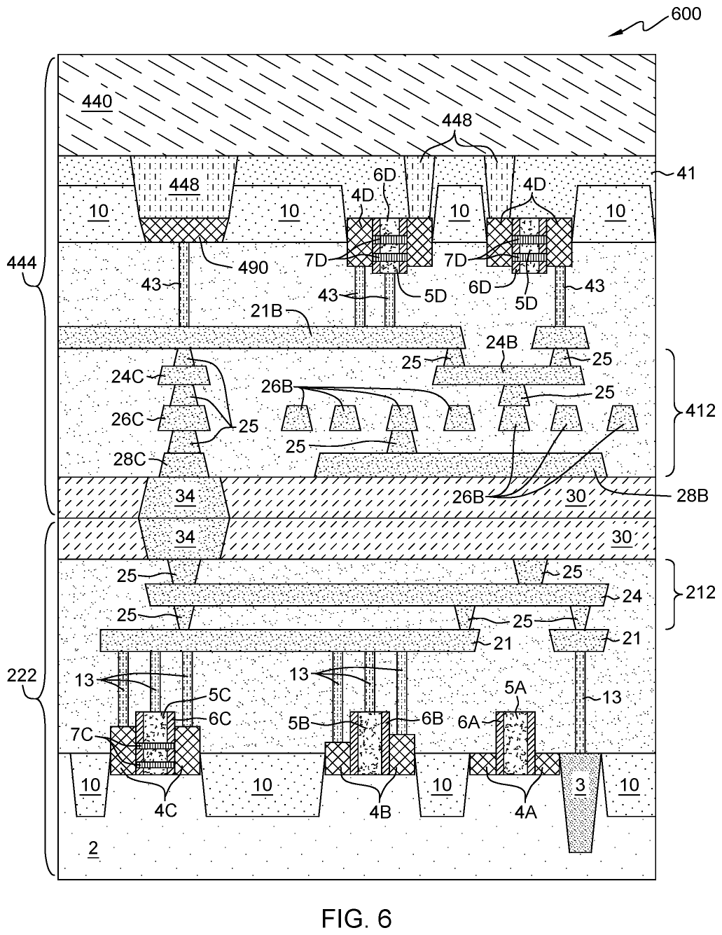

FIG. 6 depicts a cross-sectional view of another example of second semiconductor structure 444 with backside interconnect wiring 440 bonded to first wafer 222, in accordance with an embodiment of the present invention. Semiconductor structure 600 is another example of the two bonded wafers after removing one wafer to form backside interconnect wiring 440 on second semiconductor structure 444 where second semiconductor structure 444 is without a wafer substrate. Semiconductor structure 600 is similar to semiconductor structure 400. Semiconductor structure 600 depicts one specific example of the semiconductor devices that can be on first wafer 222 and second semiconductor structure 444.

As depicted, FIG. 6 includes first wafer 222 with semiconductor substrate 2, trench device 3, STI 10, a rightmost finFET device formed with source/drain (S/D) 4A, gate high-k work function metal 5A with a gate dielectric (not depicted), gate spacer 6A, a leftmost finFET device formed with S/D 4B, high-k work function metal gate 5B, gate spacer 6B, a GAA FET formed with S/D 4C, high-k work function metal gate 5C with a gate dielectric (not depicted), gate spacer dielectric 6C, and channels 7C, contacts 13 which can be device contacts such as S/D contacts and gate contacts, interconnect wiring 212, metal layer 21 which can be a M1 metal layer, vias 25, metal layer 24, bond layer 30 which can be an oxide layer on first wafer 222, metal plug 34 on a top surface of first wafer 222, metal plug 34 in surface of second wafer second semiconductor structure 444 bonded to metal plug 34 on first wafer 222, bond layer 30 on second semiconductor structure wafer 444 which can be an oxide layer bonded to bond layer 30 of first wafer 222, second semiconductor structure wafer 444 includes metal layer 28 with via pad 28C, metal layer 26B, via pad 26C, metal layer 21B which can be a M1 metal layer, contacts 43, passive device 490, STI 10, BILD 41, interconnect wiring 442, two GAA FETs each formed with S/D 4D, high-k work function metal gate 5B with a gate dielectric (not depicted), gate spacer 6B, a GAA FET formed with S/D 4C, high-k work function metal gate 5D, gate spacer 6D where backside contacts 448 connect to backside interconnect wiring 440.

As depicted in FIG. 6, second semiconductor structure 444 does not include a wafer or a wafer substrate and does include backside interconnect wiring 440. Semiconductor structure 600 depicts second semiconductor structure 444 without a wafer and with backside interconnect wiring 440. Second semiconductor structure 444 is bonded, using hybrid bonding and metal plugs 34 and bond layer 30, to first wafer 222 with semiconductor substrate 2 and trench devices 3 formed in semiconductor substrate 2. Semiconductor structure 600 provides first wafer 222 with the ability to form trench devices bonded to second semiconductor structure 444 without a wafer substrate and with backside interconnect wiring. Both first wafer 222 and second semiconductor structure 444 are electrically connected by one or more of the metal plugs and include a number of different types of devices.

In various embodiments, after forming the backside interconnect wiring on the second wafer of the two bonded wafers, the two bonded wafers joined by the bond layer and metal plugs are diced forming more than one semiconductor chip with at least the elements depicted in FIG. 6. In an embodiment, the two bonded wafers form a semiconductor chip.

FIG. 7 depicts a cross-sectional view of semiconductor structure 700 after depositing TMI 701 to the exposed surface of semiconductor substrate 2 and adding cooling plate 711, in accordance with an embodiment of the present invention. As depicted, semiconductor structure 700 of FIG. 7 includes the elements of FIG. 4 with TMI 701 and cooling plate 711 along with additional super vias 125, super vias 125A, thermal contacts 48T and 8T.

Thermal vias 48T connect backside interconnect wiring 42 to thermal contact 8T. Thermal contact 8T connects to super via 125. Super via 125 connects to metal plug 121 in bond layer 120 on frontside interconnect wiring 112B. The metal plug 121 under super via 125 connects to metal plug 121 on super via 125A where metal plug 121 on super via 125A is in bond layer 120 on frontside interconnect wiring 112. Thermal vias 48T, thermal contact 8T. super via 125, bonded metal plugs 121, and super via 125A create a thermal path to remove heat from backside interconnect wiring 42 to semiconductor substrate 2 and through TMI 701 to cooling plate 711.

TIM 701 can be any thermal interface material used to conduct heat from the surface of a semiconductor chip or wafer to a cooling element such as heat sink or cooling plate 711. In some embodiments, TIM 701 is not present. Cooling plate 711 can be composed of any heat conductive material. In various embodiments, cooling plate 711 is composed of copper. In some embodiments, cooling plate 711 is composed of aluminum. While cooling plate 711 is depicted as flat plate, cooling plate 711 can be any type of cooling element such as a fin-type heat sink, a heat sink or cooling plate with interior fins or elements, or a heat sink or cooling plate with circulating cold air or cold fluid (e.g., water) to aide in removing heat from semiconductor structure 700.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

1. A semiconductor structure comprising:
at least two layers of semiconductor devices, wherein a first layer of the semiconductor devices contacts a semiconductor substrate and connects to a first frontside interconnect wiring, and wherein a second layer of the semiconductor devices connects to a second frontside interconnect wiring and a backside power delivery network.

2. The semiconductor structure of claim 1, wherein the first frontside interconnect wiring connects by one or more first metal plugs in a first dielectric layer to one or more second metal plugs in a second dielectric layer, and wherein the second metal plugs electrically connect to a first super via in the second frontside interconnect wiring.

3. The semiconductor structure of claim 1, wherein the first layer of semiconductor devices includes one or more trench devices in at least a portion of the semiconductor substrate.

4. The semiconductor structure of claim 3, wherein the one or more trench devices in the at least the portion of the semiconductor substrate includes a semiconductor device selected from the group composed of an active semiconductor device and passive semiconductor device.

5. The semiconductor structure of claim 3, wherein the one or more trench devices include an embedded random-access memory device.

6. The semiconductor structure of claim 2 wherein the first super via connects to the second layer of semiconductor devices by one or more contacts contacting a first metal layer.

7. The semiconductor structure of claim 2, further comprising:
one or more thermal contacts contacting the backside power delivery;
one or more of the first super vias contacting the one or more thermal contacts;
the one or more second metal plugs in the second dielectric layer contacting the one or more first metal plugs in the first dielectric layer;
one or more second super vias connecting the one or more first metal plugs to the semiconductor substrate.

8. The semiconductor structure of claim 7, further comprising a cooling plate connected to the semiconductor substrate by at least a thermal interface material.

9. A semiconductor structure comprising:
a semiconductor substrate with a first plurality of semiconductor devices;
a first frontside interconnect wiring connecting by one or more first contacts to the first plurality of semiconductor devices;
a second bond layer electrically connecting with a first bond layer;
a second frontside interconnect wiring connecting the second bond layer and the one or more first contacts to a second plurality of semiconductor devices; and
a plurality of backside contacts connecting the second plurality of semiconductor devices to a backside power delivery network.

10. The semiconductor structure of claim 9, wherein the first plurality of semiconductor devices directly contacting the semiconductor substrate further comprises:
at least one semiconductor device in a portion of the semiconductor substrate; and
the second plurality of semiconductor devices are each directly contacting one of the plurality of backside contacts and a backside dielectric layer.

11. The semiconductor structure of claim 9, wherein the first bond layer includes at least one first metal plug in a first oxide layer.

12. The semiconductor structure of claim 11, wherein the second bond layer includes at least one second metal plug in a second oxide layer, and wherein the at least one second metal plug and the at least one first metal plug are electrically connected.

13. The semiconductor structure of claim 10, wherein the at least one semiconductor device residing in the portion of the semiconductor substrate is a deep trench decoupling capacitor.

14. The semiconductor structure of claim 10, wherein the at least one semiconductor device residing in the portion of the semiconductor substrate is an embedded random-access memory devices.

15. The semiconductor structure of claim 9, wherein the first plurality of semiconductor devices includes at least one finFET device.

16. The semiconductor structure of claim 10, wherein each of the second plurality of semiconductor devices reside between two isolation trenches on the at least a portion of the backside dielectric layer.

17. A method of forming a semiconductor structure comprising:
forming a first plurality of semiconductor devices on a first wafer substrate with a first frontside interconnect wiring, wherein the first plurality of semiconductor devices includes at least one trench semiconductor device;
depositing a first bond layer with one or more first metal plugs;
forming a second plurality of semiconductor devices on a second wafer substrate with a second frontside interconnect wiring;
depositing a second bond layer with one or more second metal plugs;
flipping the second wafer substrate on top of the first wafer substrate;
bonding the first wafer substrate to the second wafer substrate;
removing the second wafer substrate;
forming backside interconnect wiring for a backside power delivery network; and
dicing the first wafer substrate to form one or more semiconductor chips.

18. The method of claim 17, wherein removing the second wafer substrate, further comprises:
depositing a backside dielectric layer; and
forming backside contacts to each of the second plurality of semiconductor devices.

19. The method of claim 17, wherein bonding the first wafer substrate to the second wafer substrate further comprises joining the one or more first metal plugs to the one or more second metal plugs by hybrid bonding.

20. The method of claim 17, further comprising:
depositing a thermal interface material over the first wafer substrate, wherein the first wafer substrate includes at least one first super via connecting to the one or more first metal plugs joined to the one or more second metal plugs;
at least one second super via connecting to at least one of the second metal plugs connected to at least one first super via; and
one or more thermal contacts connecting the at least one second super via to the backside power delivery network.
